(19) United States
(12) Patent Application Publication
(10) Pub. No.: US 2012/0153508 A1
(43) Pub. Date: Jun. 21, 2012

(54) THERMOSETTING DIE-BONDING FILM

(75) Inventors: Miki Hayashi, Ibaraki-shi (JP); Naohide Takamoto, Ibaraki-shi (JP); Kenji Oonishi, Ibaraki-shi (JP)

(73) Assignee: NITTO DENKO CORPORATION

(21) Appl. No.: 13/141,765

(22) PCT Filed: Dec. 22, 2009
(86) PCT No.: PCT/JP09/71292

§ 371 Date: Jun. 23, 2011

(30) Foreign Application Priority Data
Dec. 24, 2008 (JP) 2008-328341
Dec. 18, 2009 (JP) 2009-288001

(51) Int. Cl. H01L 23/488; H01L 21/60; H01L 21/78; C08L 63/00

(52) U.S. Cl. 257/783; 523/400; 523/440; 438/127; 438/464; 438/113; 257/E21.506; 257/E21.599; 257/E23.023

(57) ABSTRACT

An object of the present invention is to provide a thermosetting die-bonding film having both storage modulus and high adhering strength that are necessary in manufacturing a semiconductor device and to provide a dicing die-bonding film including the thermosetting die-bonding film. The thermosetting die-bonding film of the present invention is a thermosetting die-bonding film that is used in manufacture of a semiconductor device and includes at least an epoxy resin, a phenol resin, an acrylic copolymer, and a filler, has a storage modulus at 80 to 140° C. before thermal curing in a range of 10 kPa to 10 MPa and a storage modulus at 175° C. before thermal curing in a range of 0.1 to 3 MPa.

### BACKGROUND OF THE INVENTION

1. Field of the Invention

The present invention relates to a thermosetting die-bonding film used when a semiconductor element such as a semiconductor chip is adhered and fixed on an adherend such as a substrate or a lead frame. The present invention also relates to a dicing die-bonding film including the thermosetting die-bonding film and a dicing film layered to each other.

2. Description of the Related Art

Conventionally, silver paste has been used to bond a semiconductor chip to a lead frame or an electrode member in the step of producing a semiconductor device. The treatment for the sticking is conducted by coating a paste-form adhesive on a die pad of a lead frame, or the like, mounting a semiconductor chip on the die pad, and then setting the paste-form adhesive layer.

However, about the paste-form adhesive, the amount of the coated adhesive, the shape of the coated adhesive, and on the like are largely varied in accordance with the viscosity behavior thereof, a deterioration thereof, and on the like. As a result, the thickness of the formed paste-form adhesive layer becomes uneven so that the reliability in strength of bonding a semiconductor chip is poor. In other words, if the amount of the paste-form adhesive coated on an electrode member is insufficient, the bonding strength between the electrode member and a semiconductor chip becomes low so that in a subsequent wire bonding step, the semiconductor chip is peeled. On the other hand, if the amount of the coated paste-form adhesive is too large, this adhesive flows out to stretch over the semiconductor chip so that the characteristic becomes poor. Thus, the yield or the reliability lowers. Such problems about the adhesion treatment become particularly remarkable with an increase in the size of semiconductor chips. It is therefore necessary to control the amount of the coated paste-form adhesive frequently. Thus, the workability or the productivity is deteriorated.

In this coating step of a paste-form adhesive, there is a method of coating the adhesive onto a lead frame or a forming chip by an independent operation. In this method, however, it is difficult to make the paste-form adhesive layer even. Moreover, an especial machine or a long time is required to coat the paste-form adhesive. Thus, a dicing die-bonding film which makes a semiconductor wafer to be bonded and held in a dicing step and further gives an adhesive layer, for bonding a chip, which is necessary for a mounting step is disclosed (see, for example, JP-A-60-57342).

The dicing die-bonding film of this type has a structure in which an adhesive layer (a die-bonding film) is laminated onto a dicing film. The dicing film has a structure in which a pressure-sensitive adhesive layer is laminated onto a support base. This dicing die-bonding film is used as follows. That is, a semiconductor wafer is diced while being held by the die-bonding film, semiconductor chips are peeled off together with the die-bonding film by stretching the support base, and the chips are individually collected. Then, each semiconductor chip is adhered and fixed to an adherend such as a BT substrate or a lead frame with the die-bonding film interposed in between.

Because the storage modulus of a conventional die-bonding film is high at the die bonding temperature (for example, 80 to 140° C.) during a die bonding step, the die-bonding film does not exhibit sufficient wettability to the adherend, and there is a case where the adhering strength becomes small. As a result, there is a problem that the semiconductor chip falls from the adherend due to vibration applied in the steps or during conveyance between the steps or bending of the adherend.

Because the die-bonding film exhibits a high storage modulus also at the wire bonding temperature (for example, 175° C.) during a wire bonding step, there is a case where the adhering strength is insufficient. As a result, there is a problem that shear deformation occurs at the adhering face between the die-bonding film and the adherend due to ultrasonic vibration or heating when performing wire bonding to the semiconductor chip that is adhered and fixed to the die-bonding film, and the success rate of wire bonding decreases.

Further, in a molding step in which the semiconductor chip that is die bonded to the adherend is sealed with a sealing (molding) resin, there is a problem that the semiconductor chip may be swept away when injecting a sealing resin and the yield decreases.

### PRIOR ART DOCUMENT

### Patent Document

Patent Document 1 Japanese Patent Application Laid-Open No. 60-57342

### SUMMARY OF THE INVENTION

### Problems to be Solved by the Invention

The present invention has been made in view of the above-described problems, and an object thereof is to provide a thermosetting die-bonding film having both storage modulus and high adhering strength that are necessary in manufacturing a semiconductor device, and to provide a dicing die-bonding film including the thermosetting die-bonding film.

### Means for Solving the Problems

The present inventors investigated a thermosetting die-bonding film to solve the above-described conventional problems. As a result, it was found that the thermosetting die-bonding film exhibits good wettability and tackiness in each of the prescribed steps for manufacturing a semiconductor device by controlling the storage modulus in a prescribed numerical range, and the present invention was completed.

That is, the thermosetting die-bonding film according to the present invention is a thermosetting die-bonding film that is used in manufacture of a semiconductor device, containing at least an epoxy resin, a phenol resin, an acrylic copolymer, and a filler, wherein the storage modulus at 80 to 140° C. before thermal curing is in a range of 10 kPa to 10 MPa and the storage modulus at 175° C. before thermal curing is in a range of 0.1 to 3 MPa.

With the above-described configuration, by making the storage modulus at 80 to 140° C. be 10 kPa to 10 MPa, sufficient wettability to an adherend is exhibited and a decrease of the adhering strength is prevented when a semiconductor chip is die bonded to the adherend such as a BT substrate or a lead frame with a thermosetting die-bonding film (hereinafter sometimes referred to as “a die-bonding film”) interposed in between. As a result, the semiconductor chip is prevented from falling from the adherend due to vibration applied during conveyance after die bonding or bending of the adherend.

In the above-described configuration, by making the storage modulus at 175° C. be 0.1 to 3 MPa, sufficient adhering strength can be maintained during wire bonding of the semiconductor chip. As a result, shear deformation at the adhering face between the die-bonding film and the adherend due to ultrasonic vibration or heating is prevented when performing wire bonding to the semiconductor chip that is adhered and fixed to the die-bonding film, and the success rate of wire bonding can be improved.

Further, the semiconductor chip can be prevented from being swept away when injecting a sealing resin in sealing the semiconductor chip that is die bonded to the adherend with a sealing (molding) resin.

In the above-described configuration, the ratio X/Y, where the total weight of the epoxy resin and the phenol resin is X parts by weight and the weight of the acrylic copolymer is Y parts by weight, is preferably 0.11 to 4. By making the ratio X/Y of the total weight of the epoxy resin and the phenol resin (X parts by weight) to the weight of the acrylic copolymer (Y parts by weight) be 0.11 or more, the storage modulus at 260° C. after performing a heat treatment at 175° C. for 1 hour can be made to be 0.1 MPa or more. As a result, the die-bonding film can be prevented from peeling off in a moisture resistance solder reflow test that is used in the reliability evaluation of semiconductor related components, and the reliability can be improved. On the other hand, by making the ratio X/Y be 4 or less, the mechanical strength of the die-bonding film as a film can be increased and a self-support property can be secured.

In the above-described configuration, B/(A+B), where the total weight of the epoxy resin, the phenol resin, and the acrylic copolymer is A parts by weight and the weight of the filler is B parts by weight, is preferably 0.8 or less. By making the content of the filler to the total weight of the epoxy resin, the phenol resin, and the acrylic copolymer be 0.8 or less, the storage modulus is kept from becoming too large, and the wettability and the tackiness to the adherend can be maintained at a higher level.

In the above-described configuration, it is preferable that the epoxy resin has an aromatic ring; the phenol resin is at least any of a phenol novolak resin, a phenol biphenyl resin, and a phenol aralkyl resin; and the acrylic copolymer is at least any of a carboxyl group-containing acrylic copolymer and an epoxy group-containing acrylic copolymer.

In the above-described configuration, the average particle size of the filler is preferably in a range of 0.005 to 10 μm. By making the average particle size of the filler be 0.005 μm or more, the storage modulus is kept from becoming too large, and the wettability and the tackiness to the adherend can be maintained at a higher level. On the other hand, by making the average particle size be 10 μm less, an effect of reinforcing the die-bonding film can be obtained, and the heat resistance can be improved.

In the above-described configuration, the weight average molecular weight of the epoxy resin is preferably in a range of 300 to 1500. By making the weight average molecular weight of the epoxy resin be 300 or more, mechanical strength, heat resistance, and humidity resistance of the die-bonding film after thermal curing can be prevented from decreasing. On the other hand, by making the weight average molecular weight be 1500 or less, the die-bonding film after thermal curing becomes rigid and is prevented from becoming brittle.

In the above-described configuration, the weight average molecular weight of the phenol resin is preferably in a range of 300 to 1500. By making the weight average molecular weight of the phenol resin be 300 or more, sufficient toughness can be given to the cured product of the epoxy resin. On the other hand, by making the weight average molecular weight be 1500 or less, the die-bonding film is kept from having high viscosity, and good workability can be maintained.

In the above-described configuration, the weight average molecular weight of the acrylic copolymer is preferably in a range of 100,000 to 1,000,000. By making the weight average molecular weight of the acrylic copolymer be 100,000 or more, the tackiness to the surface of the adherend such as a wiring board at high temperature becomes excellent and the heat resistance can be improved. On the other hand, by making the weight average molecular weight be 1,000,000 or less, the acrylic copolymer can be dissolved easily in an organic solvent.

In the above-described configuration, the glass transition temperature is preferably in a range of 10 to 50° C. By making the glass transition temperature of the die-bonding film be 10° C. or more, the adhesive that constitutes the die-bonding film can be prevented from overflowing during die bonding of a semiconductor chip. On the other hand, by making the glass transition temperature 50° C. or less, the wettability and the tackiness to the adherend can be maintained at a higher level.

In order to solve the above-described problems, the dicing die-bonding film according to the present invention has a structure in which the thermosetting die-bonding film according to any one of the above descriptions is laminated onto a dicing film.

### Effects of the Invention

The present invention has the effects described below by the means that are explained above.

According to the present invention, because the storage modulus at 80 to 140° C. is in a range of 10 kPa to 10 MPa and the storage modulus at 175° C. is in a range of 0.1 to 3 MPa, good wettability and tackiness to the adherend such as a BT substrate or a lead frame can be exhibited. As a result, the semiconductor chip can be kept adhered and fixed to the adherend when die bonding the semiconductor chip to the adherend with the thermosetting die-bonding film of the present invention interposed in between, when wire bonding the semiconductor chip after die bonding, and when sealing the semiconductor chip that is die bonded to the adherend with a resin, for example. That is, the configuration of the present invention can provide a thermosetting die-bonding film that enables a semiconductor device manufacture with an improved yield.

### BRIEF DESCRIPTION OF THE DRAWINGS

FIG. 1 is a schematic sectional view showing a dicing die-bonding film according to one embodiment of the present invention;

FIG. 2 is a schematic sectional view showing another dicing die-bonding film according to the embodiment;

FIG. 3 is a schematic sectional view showing en example in which a semiconductor chip is mounted through a die-bonding film in the dicing die-bonding film;

FIG. 4 is a schematic sectional view showing en example in which a semiconductor chip is three-dimensionally mounted through a die-bonding film in the dicing die-bonding film; and

FIG. 5 is a schematic sectional view showing an example in which two semiconductor chip are three-dimensionally mounted by a die-bonding film through a spacer using the dicing die-bonding film.

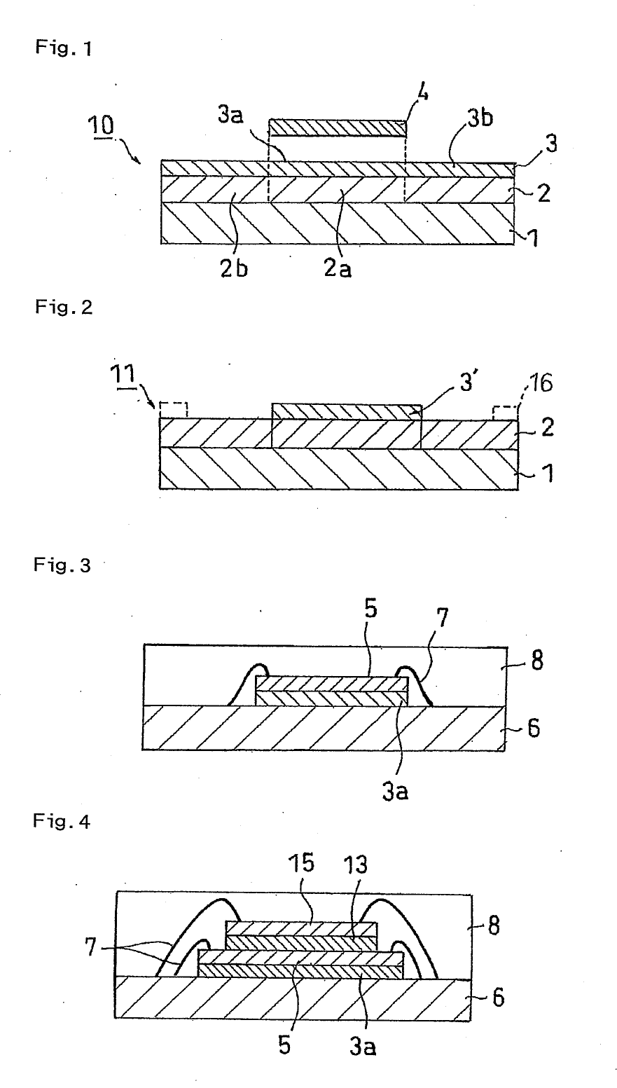

The thermosetting die-bonding film of the present invention (hereinafter referred to as a “die-bonding film”) is explained below using an embodiment of a dicing die-bonding film as an example. A dicing die-bonding film 10 of the present embodiment has a structure in which a die-bonding film 3 is laminated onto a dicing film (refer to FIG. 1). The dicing film has a structure in which a pressure-sensitive adhesive layer 2 is laminated onto a substrate 1. The die-bonding film 3 is laminated onto the pressure-sensitive adhesive layer 2 of the dicing film.

The die-bonding film 3 of the present invention contains at least an epoxy resin, a phenol resin, an acrylic copolymer, and a filler. The storage modulus of the die-bonding film 3 at 80 to 140° C. before thermal curing is in a range of 10 kPa to 10 MPa, preferably 10 kPa to 5 MPa, and more preferably 10 kPa to 3 MPa. By making the storage modulus be 10 kPa or more, the mechanical strength as a film can be increased and the self-support property can be secured. On the other hand, by making the storage modulus be 10 MPa or less, the wettability to the adherend is secured, and the adhering strength can be maintained. As a result, the semiconductor chip is prevented from falling from the adherend due to vibration applied during conveyance after die bonding or bending of the adherend.

The storage modulus of the die-bonding film 3 at 175° C. before thermal curing is in a range of 0.1 to 3 MPa, preferably 0.5 kPa to 2.5 MPa, and more preferably 0.7 kPa to 2.3 MPa. By making the storage modulus at 175° C. before thermal curing be in the above-described range, sufficient adhering strength can be maintained during wire bonding of the semiconductor chip. As a result, shear deformation at the adhering face between the die-bonding film and the adherend due to ultrasonic vibration or heating is prevented when performing wire bonding to the semiconductor chip that is adhered and fixed to the die-bonding film, and the success rate of wire bonding can be improved.

The glass transition temperature of the die-bonding film 3 is preferably 10 to 50° C., and more preferably 20 to 45° C. By making the glass transition temperature of the die-bonding film 3 be 10° C. or more, the adhesive that constitutes the die-bonding film can be prevented from overflowing during die bonding of a semiconductor chip. On the other hand, by making the glass transition temperature 50° C. or less, the wettability and the tackiness to the adherend can be maintained at a higher level.

Further, the compounded ratio X/Y(−), where the total weight of the epoxy resin and the phenol resin is X parts by weight and the weight of the acrylic copolymer is Y parts by weight, is preferably 0.11 to 4, more preferably 0.11 to 1.5, further preferably 0.11 to 1.4, especially preferably 0.11 to 1, and further more preferably 0.11 to 0.5. By making the compounded ratio X/Y be 0.11 or more, the storage modulus at 260° C. after performing a heat treatment at 175° C. for 1 hour can be made to be 0.1 MPa or more, the generation of peeling of the die-bonding film 3 can be prevented in a moisture resistance solder reflow test, and the reliability can be improved. On the other hand, by making the compounded ratio be 4 or less, the mechanical strength of the die-bonding film 3 as a film can be increased and a self-support property can be secured.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, epoxy resins having an aromatic ring such as a benzene ring, a biphenyl ring, or a naphthalene ring are especially preferable. Specific examples thereof include a novolak type epoxy resin, a xylylene skeleton-containing phenol novolak type epoxy resin, a biphenyl skeleton-containing novolak type epoxy resin, a bisphenol A type epoxy resin, a bisphenol F type epoxy resin, a tetramethylbiphenol type epoxy resin, and a triphenylmethane type epoxy resin. These epoxy resins have high reactivity with the phenol resin as a curing agent and excellent heat resistance. Further, these epoxy resins contain little ionic impurities and the like that corrode the semiconductor element.

The weight average molecular weight of the epoxy resin is preferably in a range of 300 to 1500, and more preferably in a range of 350 to 1000. When the weight average molecular weight is less than 300, the mechanical strength, the heat resistance, and the humidity resistance of the die-bonding film 3 after thermal curing may decrease. On the other hand, when it is larger than 1500, the die-bonding film after thermal curing becomes rigid and may become brittle. The weight average molecular weight in the present invention means a polystyrene conversion value from an analytical curve of a polystyrene standard obtained by gel permeation chromatography (GPC).

The phenol resin is a resin acting as a curing agent for the epoxy resin. Examples thereof include Novolak type phenol resins such as phenol Novolak resin, phenol biphenyl resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, the biphenyl type phenol novolak resin represented by the following chemical formula and the phenolaralkyl resin are preferable, since the connection reliability of the semiconductor device can be improved.

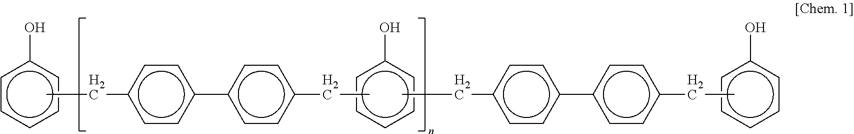

(n is a natural number of 0 to 10.)

n is preferably a natural number of 0 to 10, and more preferably a natural number of 0 to 5. By making it in the above-described range, the fluidity of die-bonding film 3 can be secured.

The weight average molecular weight of the phenol resin is preferably in a range of 300 to 1500, and more preferably in a range of 350 to 1000. When the weight average molecular weight is less than 300, thermal curing of the epoxy resin is insufficient, and sufficient toughness may not be obtained. On the other hand, when the weight average molecular weight is larger than 1500, the die-bonding film 3 is highly viscous, and workability during production of the die-bonding film may deteriorate.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

The acrylic copolymer is not especially limited, but a carboxyl group-containing acrylic copolymer and an epoxy group-containing acrylic copolymer are preferable in the present invention. Examples of the functional group monomer that is used in the carboxyl group-containing acrylic copolymer include acrylic acid and methacrylic acid. The content of acrylic acid or methacrylic acid can be adjusted so that the acid value comes into a range of 1 to 4. For the remaining part, alkyl acrylates having an alkyl group having 1 to 8 carbon atoms, such as methyl acrylate or methyl methacrylate, and a mixture of alkyl methacrylate, styrene, acrylonitrile, and the like can be used. Among these, ethyl(meth)acrylate and/or butyl(meth)acrylate are especially preferable. The mixing ratio is preferably adjusted in consideration of the glass transition point (Tg) of the acrylic copolymer described later. The polymerization method is not especially limited, and conventionally known methods such as a solution polymerization method, a bulk polymerization method, a suspension polymerization method, and an emulsion polymerization method can be adopted, for example.

Other monomer components that are copolymerizable with the above-described monomer components are not especially limited, and examples thereof include acrylonitrile. The used amount of these copolymerizable monomer components is preferably in a range of 1 to 20% by weight to all monomer components. By incorporating other monomer components in the above-described numerical range, the cohesive strength, the tackiness, and the like can be modified.

The polymerization method of the acrylic copolymer is not especially limited, and conventionally known methods such as a solution polymerization method, a bulk polymerization method, a suspension polymerization method, and an emulsion polymerization method can be adopted, for example.

The glass transition point (Tg) of the acrylic copolymer is preferably −30 to 30° C., and more preferably −20 to 15° C. By making the glass transition point be −30° C. or more, the heat resistance can be secured. On the other hand, by making it 30° C. or less, the effect of preventing chip fly after dicing improves in a wafer having a rough surface.

The weight average molecular weight of the acrylic copolymer is preferably 100,000 to 1,000,000, and more preferably 350,000 to 900,000. By making the weight average molecular weight be 100,000 or more, the tackiness at high temperature to the surface of the adherend becomes excellent, and the heat resistance can also be improved. On the other hand, by making the weight average molecular weight be 1,000,000 or less, the acrylic copolymer can be easily dissolved in an organic solvent.

Examples of the filler include an inorganic filler and an organic filler. The inorganic filler is preferable from the viewpoints of the handing property, improvement of the heat conductivity, adjustment of the melt viscosity, and impartment of a thyrotrophic property.

The inorganic filler is not especially limited, and examples thereof include silica, aluminum hydroxide, calcium hydroxide, magnesium hydroxide, antimony trioxide, calcium carbonate, magnesium carbonate, calcium silicate, magnesium silicate, calcium oxide, magnesium oxide, aluminum oxide, aluminum nitride, aluminum borate, boron nitride, crystalline silica, and amorphous silica. These may be used either alone or in combination of two or more kinds. From the viewpoint of improvement of the heat conductivity, aluminum oxide, aluminum nitride, boron nitride, crystalline silica, amorphous silica, and the like are preferable. From the viewpoint of a balance with the tackiness of the die-bonding film 3, silica is preferable. Further, examples of the organic filler include polyimide, polyamideimide, polyether ether ketone, polyetherimide, polyesterimide, nylon, and silicone. These may be used either alone or in combination of two or more kinds.

The average particle size of the filler is preferably 0.005 to 10 μm, and more preferably 0.05 to 1 μm. When the average particle size of the filler is 0.005 μm or more, the wettability to the adherend can be made good, and a decrease of the tackiness can be suppressed. On the other hand, by making the average particle size be 10 μm or less, the effect of reinforcing the die-bonding film 3 by adding the filler can be enhanced, and the heat resistance can be improved. Fillers having different average particle sizes from each other may be used in combination. The average particle size of the filler is a value obtained with a light intensity type particle size distribution meter (manufactured by HORIBA, Ltd., device name: LA-910).

The shape of the filler is not especially limited, and a spherical filler and an oval filler can be used, for example.

The ratio B/(A+B), where the total weight of the epoxy resin, the phenol resin, and the acrylic copolymer is A parts by weight and the weight of the filler is B parts by weight, is preferably more than 0 and 0.8 or less, and more preferably more than 0 and 7 or less. If the ratio is 0, there is no reinforcing effect due to addition of the filler, and the heat resistance of the die-bonding film 3 tends to decrease. On the other hand, when the ratio exceeds 0.8, the wettability and the tackiness to the adherend may decrease.

If necessary, other additives may be incorporated into the die-bonding film 3, 3′ of the present invention. Examples thereof include a flame retardant, a silane coupling agent, and an ion trapping agent.

Examples of the flame retardant include antimony trioxide, antimony pentaoxide, and brominated epoxy resin. These may be used alone or in combination of two or more thereof.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof.

Examples of the ion trapping agent include hydrotalcite and bismuth hydroxide. These may be used alone or in combination of two or more thereof.

The thermal curing-accelerating catalyst for the epoxy resin and the phenol resin is not especially limited, and a preferred example thereof is a salt consisting of any of a triphenylphosphine skeleton, an amine skeleton, a triphenylborane skeleton, a trihalogenborane skeleton, and the like.

The thickness of the die-bonding film 3, 3′ (in the case that the film is a laminate, the total thickness thereof) is not particularly limited, and is, for example, from about 5 to 100 μm, preferably from about 5 to 50 μm.

The die-bonding film may have a configuration consisting only of a single adhesive layer, for example. It may have a multi-layered structure of two layers or more in which thermoplastic resins having different glass transition temperatures and thermosetting resins having different thermal curing temperatures are appropriately combined. Because cutting water is used in the dicing step of a semiconductor wafer, the die-bonding film absorbs moisture, and may have a water content exceeding that in a normal state. When the die-bonding film and the like with such a high water content are adhered to a substrate, water vapor builds up on the adhering interface in the step of after curing, and floating may occur. Therefore, by making the die-bonding film have a configuration in which a core material having high moisture permeability is sandwiched between adhesive layers, water vapor diffuses through the film in the step of after curing, and such a problem can be avoided. From such a viewpoint, the die-bonding film may have a multi-layered structure in which the adhesive layer is formed on one surface or both surfaces of the core material.

Examples of the core material include a film such as a polyimide film, a polyester film, a polyethylene terephthalate film, a polyethylene naphthalate film, or a polycarbonate film, a resin substrate that is reinforced with glass fibers or plastic nonwoven fibers, a mirror silicon wafer, a silicon substrate, and a glass substrate.

The die-bonding film 3 is preferably protected by a separator (not shown). The separator has a function as a protecting material that protects the die-bonding film 3 until they are practically used. Further, the separator can be used as a supporting base material when transferring the die-bonding films 3, 3′ to the dicing film. The separator is peeled when pasting a workpiece onto the die-bonding film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The dicing die-bonding film according to the present invention may have a configuration of a dicing die-bonding film 11 in which a die-bonding film 3′ is laminated only onto a semiconductor wafer pasting portion as shown in FIG. 2, in addition to the configuration of the die-bonding film 3 shown in FIG. 1.

The base 1 serves as a base body for strength of the dicing die-bonding films 10 and 11. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene (meth) acrylic acid copolymer; an ethylene (meth) acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper. When the pressure-sensitive adhesive layer 2 is of an ultraviolet-ray curing-type, the base 1 preferably has transparency to an ultraviolet ray.

Further, the material of the base material 1 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 2 and the die-bonding films 3, 3′ is reduced by thermally shrinking the base material 1 after dicing, and the recovery of the semiconductor chips can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base material 1 in order to improve adhesiveness, holding properties, etc. with the adjacent layer.

The same type or different type of base material can be appropriately selected and used as the base material 1, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 1 in order to give an antistatic function to the base material 1. The base material 1 may be a single layer or a multi layer of two or more types.

The thickness of the base material 1 can be appropriately decided without limitation particularly. However, it is generally about 5 to 200 μm.

The pressure-sensitive adhesive layer 2 is constituted by containing a ultraviolet curable pressure sensitive adhesive. The ultraviolet curable pressure sensitive adhesive can easily decrease its adhesive strength by increasing the degree of crosslinking by irradiation with ultraviolet. By radiating only a part 2a corresponding to the semiconductor wafer pasting part of the pressure-sensitive adhesive layer 2 shown in FIG. 2, a difference of the adhesive strength to another part 2b can be also provided.

Further, by curing the ultraviolet curable pressure-sensitive adhesive layer 2 with the die-bonding film 3′ shown in FIG. 2, the part 2a in which the adhesive strength is remarkably decreased can be formed easily. Because the die-bonding film 3′ is pasted to the part 2a in which the adhesive strength is decreased by curing, the interface of the part 2a of the pressure-sensitive adhesive layer 2 and the die-bonding film 3′ has a characteristic of being easily peeled during pickup. On the other hand, the part not radiated by ultraviolet rays has sufficient adhesive strength, and forms the part 2b.

As described above, in the pressure-sensitive adhesive layer 2 of the dicing die-bonding film 10 shown in FIG. 1, the part 2b formed by a non-cured ultraviolet curable pressure sensitive adhesive sticks to the die-bonding film 3, and the holding force when dicing can be secured. In such a way, the ultraviolet curable pressure sensitive adhesive can support the die-bonding film 3 for fixing the semiconductor chip onto an adherend such as a substrate with good balance of adhesion and peeling. In the pressure-sensitive adhesive layer 2 of the dicing die-bonding film 11 shown in FIG. 2, a dicing ring 16 can be fixed to the part 2b. The adherend 6 is not especially limited, and examples thereof include various substrates such as a BGA substrate, a lead frame, a semiconductor element, and a spacer.

The ultraviolet curable pressure sensitive adhesive that is used has a ultraviolet curable functional group of a radical reactive carbon-carbon double bond, etc., and adherability. Examples of the ultraviolet curable pressure sensitive adhesive are an added type ultraviolet curable pressure sensitive adhesive in which a ultraviolet curable monomer component or an oligomer component is compounded into an acryl pressure sensitive adhesive or a rubber pressure sensitive adhesive.

The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acryl polymers include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth) acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer (s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 30000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The pressure-sensitive adhesive may be blended not only with the components described above but also with a wide variety of conventionally known additives such as a tackifier, and aging inhibitor, if necessary.

Examples of the ultraviolet curable monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane diol di(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the ultraviolet ray curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type ultraviolet curable pressure sensitive adhesive described above, the ultraviolet curable pressure sensitive adhesive includes an internal ultraviolet curable pressure sensitive adhesive using an acryl polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with anyone of the hydroxyl-containing monomers exemplified above, or an ether compound such as 2-hydroxyethyl vinyl ether, 4-hydroxybutyl vinyl ether or diethylene glycol monovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

Further, examples of the ultraviolet curing type pressure-sensitive adhesive which is used in the formation of the pressure-sensitive adhesive layer 2 include such as a rubber pressure-sensitive adhesive or an acryl pressure-sensitive adhesive which contains an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt compound, which are disclosed in JP-A No. 60-196956. Examples of the above addition-polymerizable compound having two or more unsaturated bonds include such as polyvalent alcohol ester or oligoester of acryl acid or methacrylic acid and an epoxy or a urethane compound.

The method of forming the part 2a in the pressure-sensitive adhesive layer 2 includes a method of forming the ultraviolet curable pressure-sensitive adhesive layer 2 on the base material 1 and then radiating the part 2a with ultraviolet partially and curing. The partial ultraviolet irradiation can be performed through a photo mask in which a pattern is formed which is corresponding to a part 3b, etc. other than the semiconductor wafer pasting part 3a. Further, examples include a method of radiating in a spot manner and curing, etc. The formation of the ultraviolet curable pressure-sensitive adhesive layer 2 can be performed by transferring the pressure-sensitive adhesive layer provided on a separator onto the base material 1. The partial ultraviolet curing can be also performed on the ultraviolet curable pressure-sensitive adhesive layer 2 provided on the separator.

In the pressure-sensitive adhesive layer 2 of the dicing die-bonding film 10, the ultraviolet irradiation may be performed on a part of the pressure-sensitive adhesive layer 2 so that the adhesive strength of the part 2a becomes smaller than the adhesive strength of other parts 2b. That is, the part 2a in which the adhesive strength is decreased can be formed by using those in which the entire or a portion of the part other than the part corresponding to the semiconductor wafer pasting part 3a on at least one face of the base material 1 is shaded, forming the ultraviolet curable pressure-sensitive adhesive layer 2 onto this, then radiating ultraviolet, and curing the part corresponding the semiconductor wafer pasting part 3a. The shading material that can be a photo mask on a supporting film can be manufactured by printing, vapor deposition, etc. Accordingly, the dicing die-bonding film 10 of the present invention can be produced with efficiency.

When curing inhibition due to oxygen occurs during irradiation with an ultraviolet ray, oxygen (air) is desirably shut off from the surface of the ultraviolet-ray curing-type pressure-sensitive adhesive layer 2. Examples of the method for shutting off oxygen (air) include a method of coating the surface of the pressure-sensitive adhesive layer 2 with a separator and a method of irradiating the pressure-sensitive adhesive layer 2 with an ultraviolet ray such as an ultraviolet ray in a nitrogen gas atmosphere.

The thickness of the pressure-sensitive adhesive layer 2 is not especially limited, but it is preferably about 1 to 50 μm from the viewpoints of preventing cracking of the chip cut surface, compatibility of fixing and holding of the adhesive layer, and the like. It is preferably 2 to 30 μm, and further preferably 5 to 25 μm.

### (Method of Manufacturing a Semiconductor Device)

Next, a method of manufacturing a semiconductor device using the dicing die-bonding film 10 according to the present embodiment is explained below.

First, as shown in FIG. 1, a semiconductor wafer 4 is press bonded to a semiconductor wafer pasting portion 3a of the adhesive layer 3 in the dicing die-bonding film 10 and is fixed by adhering and holding (a mounting step). This step is performed while pressing the semiconductor wafer 4 by a pressing means such as a pressure roll.

Next, the dicing of the semiconductor wafer 4 is performed. Accordingly, the semiconductor wafer 4 is cut into a prescribed size and individualized, and a semiconductor chip 5 is produced. The dicing is performed following a normal method from the circuit face side of the semiconductor wafer 4, for example. Further, the present step can adopt such as a cutting method called full-cut that forms a slit in the dicing die-bonding film 10. The dicing apparatus used in the present step is not particularly limited, and a conventionally known apparatus can be used. Further, because the semiconductor wafer 4 is adhered and fixed by the dicing die-bonding film 10, chip crack and chip fly can be suppressed, and at the same time the damage of the semiconductor wafer can be also suppressed.

Pickup of the semiconductor chip 5 is performed in order to peel a semiconductor chip 5 that is adhered and fixed to the dicing die-bonding film 10. The method of picking up is not particularly limited, and conventionally known various methods can be adopted. Examples include a method of pushing up the individual semiconductor chip 5 from the dicing die-bonding 10 side with a needle and picking up the pushed semiconductor chip 5 with a picking-up apparatus.

The pickup is performed after irradiating the pressure-sensitive adhesive layer 2 with an ultraviolet ray when the pressure-sensitive adhesive layer 2 is of an ultraviolet-ray curing-type. Accordingly, the adhesive strength of the pressure-sensitive adhesive layer 2 to the adhesive layer 3a decreases, and the peeling of the semiconductor chip 5 becomes easy. As a result, picking up becomes possible without damaging the semiconductor chip 5. The condition such as irradiation intensity and irradiation time when irradiating an ultraviolet ray is not particularly limited, and it may be appropriately set depending on necessity. Further, the light source as described above can be used as a light source used in the ultraviolet irradiation.

Next, as shown in FIG. 3, the semiconductor chip 5 that is formed by dicing is die bonded to an adherend 6 with the die-bonding film 3a interposed in between. The die bonding is performed by press bonding. The condition of die bonding is not especially limited, and can be set appropriately as necessary. Specifically, the die bonding can be performed at a die bonding temperature of 80 to 160° C., a bonding pressure of 5 to 15 N, and a bonding time of 1 to 10 seconds, for example.

Next, the semiconductor chip 5 and the adherend 6 are adhered to each other by thermally curing the die-bonding film 3a by performing a heat treatment on the film. The heat treatment condition is preferably a temperature of 80 to 180° C., and a heating time of 0.1 to 24 hours, preferably 0.1 to 4 hours, and more preferably 0.1 to 1 hour.

Then, a wire bonding step is performed, in which the tip of the terminal part (inner lead) of the adherend 6 and an electrode pad (not shown in the drawings) on the semiconductor chip 5 are electrically connected to each other with a bonding wire 7. The bonding wires 7 may be, for example, gold wires, aluminum wires, or copper wires. The temperature when the wire bonding is performed is from 80 to 250° C., preferably from 80 to 220° C. The heating time is from several seconds to several minutes. The connection of the wires is performed by using a combination of vibration energy based on ultrasonic waves with compression energy based on the application of pressure in the state that the wires are heated to a temperature in the above-mentioned range.

The die-bonding film 3a after thermal curing preferably has a shear adhering strength at 175° C. of 0.01 MPa or more, and more preferably 0.01 to 5 MPa. By making the shear adhering strength at 175° C. after thermal curing be 0.01 MPa or more, the shear deformation caused by ultrasonic vibration or heating in the wire bonding step can be prevented from occurring at the adhering face between the die-bonding film 3a and the semiconductor chip 5 or the adherend 6. That is, the semiconductor element does not move due to the ultrasonic vibration during wire bonding, and accordingly, the success rate of wire bonding is prevented from decreasing.

The wire bonding step may be performed without thermally curing the die-bonding film 3 by a heat treatment. In this case, the shear adhering strength of the die-bonding film 3a to the adherend 6 at 25° C. is preferably 0.2 MPa or more, and more preferably 0.2 to 10 MPa. By making the shear adhering strength be 0.2 MPa or more, the shear deformation caused by ultrasonic vibration or heating in this step does not occur at the adhering face between the die-bonding film 3a and the semiconductor chip 5 or the adherend 6 even when the wire bonding step is performed without thermally curing the die-bonding film 3a. That is, the semiconductor element does not move due to the ultrasonic vibration during wire bonding, and accordingly, the success rate of wire bonding is prevented from decreasing.

The uncured die-bonding film 3a is not completely thermally cured even when the wire bonding step is performed. Further, the shear adhering strength of the die-bonding film 3a is required to be 0.2 MPa or more even in a temperature range of 80 to 250° C. When the shear adhering strength is less than 0.2 MPa in this temperature range, the semiconductor element moves by the ultrasonic vibration during wire bonding and wire bonding cannot be performed, and therefore the yield decreases.

Next, a sealing step of sealing the semiconductor chip 5 with a sealing resin 8 is performed. The present step is performed by molding the sealing resin with a mold or die. The sealing resin 8 may be, for example, an epoxy resin. The heating for the resin-sealing is performed usually at 175° C. for 60 to 90 seconds. In the this invention, however, the heating is not limited to this, and may be performed, for example at 165 to 185° C. for several minutes. With this operation, the sealing resin is cured, and the die-bonding film 3a is also thermally cured if it has not been thermally cured. That is, in the present invention, the die-bonding film 3a can be adhered by thermal curing in this step even if a post curing step that is described later is not performed, and the present invention can contribute to reduction in the number of manufacturing steps and shortening of the manufacturing period of a semiconductor device.

In the post-curing step, the sealing resin 8, which is not sufficiently cured in the sealing step, is completely cured. Even if the die-bonding film 3a is not completely cured in the step of sealing, the die-bonding film 3a and sealing resin 8 can be completely cured in the present step. The heating temperature in the present step is varied dependently on the kind of the sealing resin, and is, for example, in the range of 165 to 185° C. The heating time is from about 0.5 to 8 hours.

The dicing die-bonding film of the invention also can be preferably used in the case of three-dimensional mounting also in which plural semiconductor chips are laminated, as illustrated in FIG. 4. FIG. 4 is a schematic sectional view illustrating an example wherein semiconductor chips are three-dimensionally mounted through a die-bonding film. In the case of the three-dimensional mounting illustrated in FIG. 4, at least one die-bonding film 3a cut out so as to have a size equal to that of a semiconductor chip 5 is bonded to a adherend 6, and then the semiconductor chip 5 is bonded onto the adherend 6 through the die-bonding film 3a so as to direct its wire bonding face upwards. Next, a die-bonding film 13 is bonded onto the semiconductor chip 5 avoiding its electrode pad portions. Furthermore, another semiconductor chip 15 is bonded onto the die-bonding film 13 so as to direct its wire bonding face upwards. After that, the strength in high temperature is increased by adhering and fixing the die-bonding films 3a and 13 by thermally curing them. As the heating condition, the same as described above, the temperature is preferably in a range of 80 to 200° C. and the heating time is preferably in a range of 0.1 to 24 hours.

In the present invention, the die-bonding films 3a and 13 may be simply die bonded without thermal curing. After that, wire bonding may be performed without the heating step, the semiconductor chip may be sealed with a sealing resin, and the sealing resin may be post cured.

Next, the wire bonding step is performed. With this operation, an electrode pad of each of the semiconductor chip 5 and another semiconductor chip 15 and the adherend 6 are electrically connected to each other with a bonding wire 7. This step is carried out without going through a heating step of the die-bonding films 3a and 13.

Then, the sealing step of sealing the semiconductor chip 5, and the like with the sealing resin 8 is performed, and the sealing resin is thermally cured. At the same time, when thermal curing is not performed, the adherend 6 and the semiconductor chip 5 are adhered and fixed to each other by thermally curing the die-bonding film 3a. Further, the semiconductor chip 5 and the other semiconductor chip 15 are adhered and fixed to each other by thermally curing the die-bonding film 13. After the sealing step, an after-curing step may be performed.

In the case of the three-dimensional mounting of the semiconductor chips, the production process is simplified and the yield is improved since heating treatment by heating the die-bonding films 3a and 13 is not conducted. Furthermore, the adherend 6 is not warped, and the semiconductor chips 5 and 15 are not cracked; thus, the semiconductor element can be made still thinner.

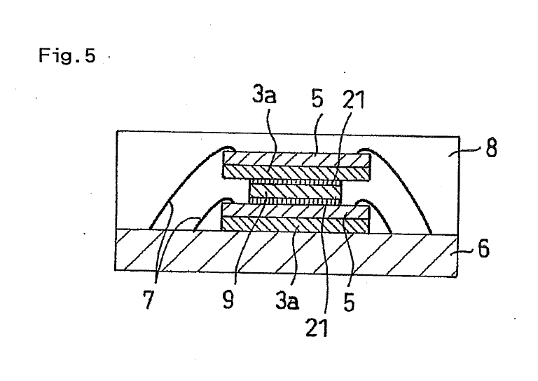

Three-dimensional mounting may performed in which semiconductor chips are laminated through die-bonding films so as to interpose a spacer between the semiconductor chips, as illustrated in FIG. 5. FIG. 5 is a schematic sectional view illustrating an example wherein two semiconductor chips are three-dimensionally mounted through die-bonding films so as to interpose a spacer between the chips.

In the case of the three-dimensional mounting illustrated in FIG. 5, first, a die-bonding film 3, a semiconductor chip 5, and a die-bonding film 21 are successively laminated on the adherend 6 to bond these members. Furthermore, on the die-bonding film 21 are successively laminated a spacer 9, another die-bonding film 21, another die-bonding film 3a, and another semiconductor chip 5 to bond these members. After that, the strength in high temperature is increased by adhering and fixing the die-bonding films 3a and 21 by thermally curing them. As the heating condition, the same as described above, the temperature is preferably in a range of 80 to 200° C. and the heating time is preferably in a range of 0.1 to 24 hours.

In the present invention, the die-bonding films 3a and 21 may be simply die bonded without thermal curing. After that, wire bonding may be performed without going through the heating step, the semiconductor chip may be sealed with a sealing resin, and the sealing resin may be post cured.

Next, as shown in FIG. 5, the wire bonding step is performed. With this operation, an electrode pad of the semiconductor chip 5 and the adherend 6 are electrically connected to each other with the bonding wire 7. This step is carried out without going through a heating step of the die-bonding films 3a and 21.

Then, the sealing step of sealing the semiconductor chip 5 with the sealing resin 8 is performed. The sealing resin 8 is thermally cured, and when the die-bonding films 3a and 21 are uncured, the adherend 6 and the semiconductor chip 5, and the semiconductor chip 5 and a spacer 9, are adhered and fixed to each other by thermally curing the die-bonding films 3a and 21. In this way, a semiconductor package is obtained. The sealing step is preferably performed by a package sealing method wherein only the semiconductor chip 5 is sealed. The sealing is performed to protect the semiconductor chips 5 adhered onto the adhesive sheet(s). The method therefor is typically a method of using the sealing resin 8 and molding the resin 8 in a metal mold. At this time, it is general to use a metal mold composed of an upper metal mold part and a lower metal mold part and having plural cavities to seal simultaneously. The heating temperature at the time of the sealing preferably ranges, for example, from 170 to 180° C. After the sealing step, an after-curing step may be performed.

The spacer 9 is not particularly limited, and may be made of, for example, a silicon chip or polyimide film and the like known in the prior art. The spacer may be a core member. The core member is not particularly limited, and may be a core member known in the prior art. Specific examples thereof include films (such as a polyimide film, a polyester film, a polyethylene terephthalate film, a polyethylene naphthalate film, a polycarbonate film and the like), resin substrates each reinforced with glass fiber or plastic nonwoven fiber, mirror silicon wafers, silicon substrates, and glass adherends.

### (Other Matters)

When semiconductor elements are three-dimensionally mounted on the above-mentioned adherend, a buffer court film is formed on the side where the circuit of the semiconductor element is formed. The buffer court film includes high-temperature resins such as the nitride silicon films or the polyimide resins for instance.

Moreover, when semiconductor elements are three-dimensionally mounted, the die-bonding film used in each steps is not limited to the same composition and can be properly changed according to the manufacturing condition, the usage, and the like.

Moreover, in the above-mentioned embodiment, the wire bonding process is done in bulk after semiconductor elements are accumulated to the adherend. Present invention, however, is not limited to the embodiment. For instance, it is also possible to do the wire bonding process every time the semiconductor element is accumulated on the adherend.

### EXAMPLES

Preferred examples of the present invention are explained in detail below. However, materials, compounded amounts, and the like described in these examples are not meant to limit the scope of the present invention as long as there is no special restrictive description, and they are only explanatory examples. Further, “part(s)” in examples means “part(s) by weight”.

### Example 1

An adhesive composition with a concentration of 20.7% by weight was prepared by dissolving 6.25 parts of an epoxy resin (Epicoat 834 manufactured by Japan Epoxy Resin Co., Ltd., weight average molecular weight: 470), 12.5 parts of a phenol resin (Tamanol 100S manufactured by Arakawa Chemical Industries, Ltd., weight average molecular weight: 900), and 54 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 800,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film A having a thickness of 40 μm was produced.

### Example 2

An adhesive composition with a concentration of 21.5% by weight was prepared by dissolving 12.5 parts of an epoxy resin (Epicoat 834 manufactured by Japan Epoxy Resin Co., Ltd., weight average molecular weight: 470), 12.5 parts of a phenol resin (Tamanol 100S manufactured by Arakawa Chemical Industries, Ltd., weight average molecular weight: 900), and 83 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 800,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film B having a thickness of 40 μm was produced.

### Example 3

An adhesive composition with a concentration of 20.5% by weight was prepared by dissolving 7 parts of an epoxy resin (Epicoat 834 manufactured by Japan Epoxy Resin Co., Ltd., weight average molecular weight: 470), 7 parts of a phenol resin (Tamanol 100S manufactured by Arakawa Chemical Industries, Ltd., weight average molecular weight: 900), and 85 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 800,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film C having a thickness of 40 μm was produced.

### Example 4

An adhesive composition with a concentration of 21.0% by weight was prepared by dissolving 85 parts of an epoxy resin (Epicoat 834 manufactured by Japan Epoxy Resin Co., Ltd., weight average molecular weight: 470), 47 parts of a phenol resin (Tamanol 100S manufactured by Arakawa Chemical Industries, Ltd., weight average molecular weight: 900), and 232 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 400,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film D having a thickness of 40 μm was produced.

### Example 5

An adhesive composition with a concentration of 21.0% by weight was prepared by dissolving 43 parts of an epoxy resin (Epicoat 834 manufactured by Japan Epoxy Resin Co., Ltd., weight average molecular weight: 470), 23 parts of a phenol resin (Tamanol 100S manufactured by Arakawa Chemical Industries, Ltd., weight average molecular weight: 900), and 588 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 400,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film D having a thickness of 40 μm was produced.

### Comparative Example 1

In Comparative Example 1, a thermosetting die-bonding film D according to Comparative Example 1 was produced in the same manner as in Example 1 except that the content of spherical silica was changed to 1125 parts.

### Comparative Example 2

An adhesive composition with a concentration of 21.4% by weight was prepared by dissolving 250 parts of an epoxy resin 1 (Epicoat 1004 manufactured by Japan Epoxy Resin Co., Ltd., weight average molecular weight: 1400), 250 parts of an epoxy resin 2 (Epicoat 827 manufactured by Japan Epoxy Resin Co., Ltd., weight average molecular weight: 370), 500 parts of a phenol resin (Milex XLC-4L manufactured by Mitsui Chemicals, Inc., weight average molecular weight: 1385), and 667 parts of spherical silica having an average particle size of 500 nm (SO-25R manufactured by Admatechs Co., Ltd.) to 100 parts of an acrylic acid ester polymer (Paracron W-197CM manufactured by Negami Chemical Industrial Co., Ltd., weight average molecular weight: 400,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film E having a thickness of 40 μm was produced.

### Comparative Example 3

An adhesive composition with a concentration of 20.9% by weight was prepared by dissolving 3.3 parts of an epoxy resin (Epicoat 834 manufactured by Japan Epoxy Resin Co., Ltd., weight average molecular weight: 470), 1.9 parts of a phenol resin (Tamanol 100S manufactured by Arakawa Chemical Industries, Ltd., weight average molecular weight: 900), and 45 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 400,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film G having a thickness of 40 μm was produced.

### Comparative Example 4

An adhesive composition with a concentration of 20.9% by weight was prepared by dissolving 300 parts of an epoxy resin (Epicoat 828 manufactured by Japan Epoxy Resin Co., Ltd., weight average molecular weight: 370), 165 parts of a phenol resin (MEH-7500-3S manufactured by Meiwa Plastic Industries, Ltd., weight average molecular weight: 500), and 253 parts of spherical silica having an average particle size of 500 nm (SO-25R manufactured by Admatechs Co., Ltd.) to 100 parts of an acrylic acid ester polymer (Teisan Resin SG-708-6 manufactured by Nagase ChemteX Corporation, weight average molecular weight: 400,000) as an acrylic copolymer having ethyl acrylate-methyl methacrylate as a main component in methyl ethyl ketone.

This adhesive composition solution is applied onto a release treatment film (a peeling liner) made of a polyethylene terephthalate film to which a silicone release treatment was performed and having a thickness of 50 μm, and then dried at 130° C. for 2 minutes. With this operation, a thermosetting die-bonding film G having a thickness of 40 μm was produced.

### (Measurement Method of the Weight Average Molecular Weight)

The weight average molecular weight of the acrylic copolymer is a polystyrene conversion value obtained by gel permeation chromatography. The gel permeation chromatography was performed using four columns of TSK G2000H HR, G3000H HR, G4000H HR, and GMH-H HR (all manufactured by Tosoh Corporation) connected in series and using tetrahydrofuran as an eluant, under the conditions of a flow rate of 1 ml/min, a temperature of 40° C., a sample concentration of a 0.1% by weight tetrahydrofuran solution, and a sample injection amount of 500 μl, and using a differential refractometer as a detector.

### (Measurement of the Storage Modulus at 80° C., 140° C., and 175° C.)

A rectangular piece 200 μm in thickness, 25 mm in length (measured length), and 10 mm in width was cut from each of the thermosetting die-bonding films of the examples and comparative examples with a cutting knife, and the storage modulus at −50 to 300° C. was measured using a solid viscoelasticity measurement apparatus (RSA III manufactured by Rheometric Scientific FE, Ltd.). The measurement conditions were a frequency of 1 Hz and a temperature rise rate of 10° C./min. The storage moduli E₁′, E₂′, and E₃′ at 80° C., 140° C., and 175° C. are shown in Table 1.

### (Measurement of the Glass Transition Temperature (Tg))

For the glass transition point of each of the thermosetting die-bonding films according to the examples and comparative examples, the storage modulus was measured first in the same manner as in the above-described storage modulus. Then, the loss modulus was measured, and the glass transition temperature was obtained by calculating the value of tan δ (G″ (loss modulus)/G′ (storage modulus)). The result is shown in Table 1.

### (Measurement of the Shear Adhering Strength at Room Temperature)

The shear adhering strength of the thermosetting die-bonding films that were produced in the examples and comparative examples to the semiconductor element was measured as follows.

First, each of the thermosetting die-bonding films was pasted to a semiconductor chip (10 mm long×10 mm wide×0.5 mm thick) at a pasting temperature of 40° C. Next, the laminate was die attached onto a BGA substrate under conditions of a die bonding temperature of 120° C., a bonding pressure of 0.1 MPa, and a bonding time of 1 second. Next, the shear adhering strength at room temperature for each film was measured using a bond tester (dagy 4000 manufactured by Dage Japan Co., Ltd.). The result is shown in Table 1.

### (Measurement of the Shear Adhering Strength at 175° C.)

The shear adhering strength of the thermosetting die-bonding films that were produced in the examples and comparative examples to the semiconductor element was measure as follows.

A semiconductor chip (10 mm long×10 mm wide×0.5 mm thick) was die attached onto a BGA substrate with each of the thermosetting die-bonding films of the examples and comparative examples interposed in between in the same manner as in the measurement of the shear adhering strength at room temperature. Next, the shear adhering strength at 175° C. for each film was measured using a bond tester (dagy 4000 manufactured by Dage Japan Co., Ltd.). The result is shown in Table 1.

### (Evaluation of Wire Bonding Property)

The wire bonding property when wire bonding a mirror chip that was die bonded onto a BGA substrate using each of the thermosetting die-bonding films that were produced in the examples and comparative examples was evaluated.

First, a 10 mm square mirror chip was produced by dicing a silicon wafer with Al deposited onto the surface. This mirror chip was die bonded onto a BGA substrate with the thermosetting die-bonding film interposed in between. The die bonding was performed under conditions of a temperature of 120° C., 0.1 MPa, and 1 second using a die bonder (SPA-300 manufactured by Shinkawa Ltd.).

Next, wire bonding was performed 50 times on each side of the mirror chip with an Au wire 25 μm in diameter using a wire bonding apparatus (product name: Eagle 60 manufactured by ASM Pacific Technology Ltd.). The wire bonding conditions were an ultrasonic output time of 2.5 msec, an ultrasonic output of 0.75 W, a bond load of 60 g, and a stage temperature of 175° C. The evaluation of the wire bonding property was performed by confirming generation of positional deviation and chip cracking of the mirror chip. The case where the positional deviation or the chip cracking did not generate is marked O, and the case where it generated is marked x.

### (Evaluation of the Molding Property)

A semiconductor chip (10 mm long×10 mm wide×0.5 mm thick) was die attached onto a BGA substrate with each of the thermosetting die-bonding films of the examples and comparative examples interposed in between in the same manner as in the measurement of the shear adhering strength. Next, the sealing step was performed under conditions of a molding temperature of 175° C., a clamping pressure of 184 kN, a transferring pressure of 5 kN, a time of 120 seconds, and a sealing resin of GE-100 (manufactured by Nitto Denko Corporation) using a molding machine (Manual Press Y-1 manufactured by Towa Japan).

After that, the state of the semiconductor chip that was fixed onto the BGA substrate was observed using an ultrasonic video apparatus (FS200II manufactured by Hitachi Cable Fine-Tech, Ltd.). The result is shown in Table 1. In Table 1, the case where there is no positional deviation or floating by peeling of the semiconductor chip is marked O, and the case where either of them was observed is marked x.

### (Results)

As can be understood from the result in Table 1, the semiconductor chip after die bonding does not fall from the BGA substrate during conveyance in the case of the thermosetting die-bonding films of Examples 1 to 5. Further, the positional deviation and chip cracking due to shear deformation from the BGA substrate did not generate in the wire bonding step. As a result, the yield can be improved in the wire bonding step. Furthermore, the semiconductor chip was not swept away by a sealing resin during sealing with the sealing resin. Accordingly, it was confirmed that the thermosetting die-bonding films according to the examples of the present invention have both the storage modulus and high adhering strength that are necessary in manufacturing a semiconductor device.

TABLE 1

| | | Example | Example | Example | Example | Example | Comparative | Comparative | Comparative | Comparative |
|---|---|---|---|---|---|---|---|---|---|---|
| | | 1 | 2 | 3 | 4 | 5 | Example 1 | Example 2 | Example 3 | Example 4 |
| X/Y (—) | | 0.18 | 0.25 | 0.14 | 1.32 | 0.66 | 0.14 | 10 | 0.05 | 4.65 |
| B/(A + B) (—) | | 0.31 | 0.40 | 0.43 | 0.50 | 0.78 | 0.91 | 0.38 | 0.31 | 0.31 |
| E₁′ (MPa, 80° C.) | | 0.60 | 1.13 | 7.93 | 0.10 | 1.90 | 5.0 | 0.80 | 13.30 | 0.01 |
| E₂′ (MPa, 140° C.) | | 0.58 | 1.00 | 8.00 | 0.20 | 1.70 | 4.5 | 0.5 | 12.10 | 0.01 |
| E₃′ (MPa, 175° C.) | | 0.20 | 0.30 | 2.91 | 0.10 | 1.0 | 4.2 | 0.08 | 1.50 | 0.00 |
| SHEAR | ROOM | 1.45 | 1.53 | 0.82 | 1.60 | 1.0 | 0.2 | 1.00 | 0.13 | 2.02 |
| ADHERING | TEMPERATURE | | | | | | | | | |
| STRENGTH | 175° C. | 0.017 | 0.014 | 0.015 | 0.02 | 0.03 | 0.009 | 0.002 | 0.01 | 0 |

| | | | | | | | | | |
|---|---|---|---|---|---|---|---|---|---|
| Tg (° C.) | 32 | 38 | 43 | 37 | 45 | 52 | 10 | 24 | 22 |
| WIRE BONDING PROPERTY | ∘ | ∘ | ∘ | ∘ | ∘ | x | x | x | x |
| MOLDING EVALUATION | ∘ | ∘ | ∘ | ∘ | ∘ | x | x | x | x |

In the table, X (parts by weight) is the total weight of the epoxy resin and the phenol resin, and Y (parts by weight) is the weight of the acrylic copolymer. A (parts by weight) is the total weight of the epoxy resin, the phenol resin, and the acrylic copolymer, and B (parts by weight) is the weight of the filler.

### DESCRIPTION OF THE REFERENCE NUMERALS

1 BASE
2 PRESSURE-SENSITIVE ADHESIVE LAYER
3, 3′, 13, 21 THERMOSETTING DIE-BONDING FILM
4 SEMICONDUCTOR WAFER
5 SEMICONDUCTOR CHIP
6 ADHEREND
7 BONDING WIRE
8 SEALING RESIN
9 SPACER
10, 11 DICING DIE-BONDING FILM
15 SEMICONDUCTOR CHIP
16 WAFER RING

1. A thermosetting die bond film that is used in manufacture of a semiconductor device comprising at least an epoxy resin, a phenol resin, an acrylic copolymer, and a filler, wherein
the storage modulus at 80 to 140° C. before thermal curing is in a range of 10 kPa to 10 MPa and the storage modulus at 175° C. before thermal curing is in a range of 0.1 MPa to 3 MPa.

2. The thermosetting die bond film according to claim 1, wherein the ratio X/Y, where the total weight of the epoxy resin and the phenol resin is X parts by weight and the weight of the acrylic copolymer is Y parts by weight, is 0.11 to 4.

3. The thermosetting die bond film according to claim 1, wherein the ratio B/(A+B), where the total weight of the epoxy resin, the phenol resin, and the acrylic copolymer is A parts by weight and the weight of the filler is B parts by weight, is 0.8 or less.

4. The thermosetting die bond film according to claim 1, wherein the epoxy resin has an aromatic ring; the phenol resin is at least any of a phenol novolak resin, a phenol biphenyl resin, and a phenol aralkyl resin; and the acrylic copolymer is at least any of a carboxyl group-containing acrylic copolymer and an epoxy group-containing acrylic copolymer.

5. The thermosetting die bond film according to claim 1, wherein the average particle size of the filler is in a range of 0.005 to 10 μm.

6. The thermosetting die bond film according to claim 1, wherein the weight average molecular weight of the epoxy resin is in a range of 300 to 1500.

7. The thermosetting die bond film according to claim 1, wherein the weight average molecular weight of the phenol resin is in a range of 300 to 1500.

8. The thermosetting die bond film according to claim 1, wherein the weight average molecular weight of the acrylic copolymer is in a range of 100,000 to 1,000,000.

9. The thermosetting die bond film according to claim 1, wherein the glass transition temperature is in a range of 10 to 50° C.

10. A dicing die bond film having a structure in which the thermosetting die bond film according to claim 1 is laminated onto a dicing film.

11. The thermosetting die bond film of claim 1, wherein a blend ratio between the epoxy resin and the phenol resin is from 0.5 to 2.0 equivalents hydroxyl groups in the phenol resin per equivalent of epoxy groups in the epoxy resin.

12. A method of wire bonding a semiconductor device using the thermosetting die bond film of claim 1, the method comprising:
(a) providing the thermosetting die bond film;
(b) adhering a semiconductor chip to an adherend with the thermosetting die bond film interposed in between;
(c) wire bonding the adherend to the semiconductor chip; and
(d) sealing the semiconductor chip with a sealing resin.

13. A method of manufacturing a semiconductor device using the dicing die bond film of claim 10, the method comprising:
(a) providing the dicing die bond film;
(b) pressure-bonding a semiconductor wafer on the thermosetting die bond film; and
(c) dicing the semiconductor wafer together with the thermosetting die bond film to form a semiconductor chip.

14. The method of claim 13, further comprising
(d) peeling the semiconductor chip from the pressure-sensitive adhesive layer together with the die bond film;
(b) adhering a semiconductor chip to an adherend with the thermosetting die bond film interposed in between;
(c) wire bonding the adherend to the semiconductor chip; and
(d) sealing the semiconductor chip with a sealing resin.

15. A semiconductor device comprising a semiconductor chip, an adherend, and the thermosetting die bond film of claim 1 interposed in between the semiconductor chip and the adherend, wherein the semiconductor chip and the adherend are electrically connected to each other with a bonding wire.
